(19) United States
(12) Patent Application Publication
(10) Pub. No.: US 2026/0282327 A1
(43) Pub. Date: Sep. 17, 2026

(54) THINNED SEMICONDUCTOR DEVICE HAVING DOPED SEMICONDUCTIVE ZONE LOCALIZED PROXIMATE TO A MEMORY ARRAY

(71) Applicant: Micron Technology, Inc., Boise, ID (US)

(72) Inventors: Kamal M. KARDA, Boise, ID (US); Durai Vishak Nirmal RAMASWAMY, Boise, ID (US)

(21) Appl. No.: 19/450,046

(22) Filed: Jan. 15, 2026

Related U.S. Application Data
(60) Provisional application No. 63/770,869, filed on Mar. 12, 2025.

(51) Int. Cl. H10B 12/00

(52) U.S. Cl. CPC H10B 12/33; H10B 12/036; H10B 12/05

(57) ABSTRACT

Implementations described herein relate to various structures, integrated assemblies, and memory devices. In some implementations, a semiconductor device assembly includes a memory array region, an insulative layer, an intrinsic semiconductive region between the memory array region and the insulative layer, and a doped semiconductive region that is contained within a lateral zone that is between the intrinsic semiconductive region and the insulative layer.

### CROSS-REFERENCE TO RELATED APPLICATION

This Patent Application claims priority to U.S. Provisional Patent Application No. 63/770,869, filed on Mar. 12, 2025, entitled “THINNED SEMICONDUCTOR DEVICE HAVING DOPED SEMICONDUCTIVE ZONE LOCALIZED PROXIMATE TO A MEMORY ARRAY,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a semiconductor device that is thinned and has a doped semiconductive zone that is localized proximate to a memory array of the semiconductor device.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, the electronic device may write, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. A binary memory device may, for example, include a charged or discharged capacitor. A charged capacitor may, however, become discharged over time through leakage currents, resulting in the loss of the stored information. Some features of volatile memory may offer advantages, such as faster read or write speeds, while some features of non-volatile memory, such as the ability to store data without periodic refreshing, may be advantageous.

### BRIEF DESCRIPTION OF THE DRAWINGS

FIG. 1 is a circuit diagram of an example memory cell.

FIGS. 2A and 2B are diagrammatic views of example implementations of a semiconductor device structure described herein.

FIG. 3 includes diagrammatic views of example implementations of a doped semiconductive region described herein.

FIG. 4 is a flowchart of an example method of forming an integrated assembly or memory device that is thinned and that has a doped semiconductive region that is localized proximate to a memory array region.

FIGS. 5A and 5B are diagrammatic views showing formation of a semiconductor device structure at stages of an example process of forming the semiconductor device structure.

FIGS. 6A and 6B are diagrammatic views showing formation of a semiconductor device structure at stages of an example process of forming the semiconductor device structure.

FIG. 7 is a diagrammatic view of an example memory device.

### DETAILED DESCRIPTION

In the realm of memory technology, such as dynamic random access memory (DRAM) memory technology, practitioners perpetually strive to miniaturize memory arrays to improve density and performance. As feature sizes decrease, maintaining performance aspects of a memory array becomes increasingly challenging.

For example, in some cases, a reduction in size often leads to a need for a thinner memory array to accommodate fabrication of high aspect ratio (HAR) features such as trenches for isolation structure formation (e.g., shallow trench isolation regions). However, with a reduction in the thickness of the memory array, a likelihood of electrical leakage between cells of the memory array may increase. While current techniques may include implanting dopants in the memory array to mitigate the leakage, such techniques may inadvertently generate new leakage paths, ultimately exacerbating the overall leakage. As a result, a key challenge in minimizing feature sizes is managing tradeoffs between reducing a thickness of the memory array and preventing development of electrical leakage paths that compromise data integrity.

Some implementations described herein include a semiconductor device that is thinned and that has a semiconductive zone that is doped and localized proximate to the memory array of the semiconductive device. Techniques to form the semiconductor device may include using a carrier to thin the semiconductor device and using a mask to localize dopants within a semiconductive zone that is laterally arranged and that is proximate to active areas of the memory array.

In this way, the semiconductor device may have a reduced thickness to accommodate scaling needs while satisfying one or more performance thresholds related to leakage, thereby promoting miniaturization and improving a quality and/or a reliability of the semiconductor device. By promoting miniaturization and improving the quality and/or the reliability of the semiconductor device, an amount of resources used to support a market consuming the semiconductor device (e.g., raw materials, semiconductor manufacturing tools, labor, and/or computing resources) is reduced.

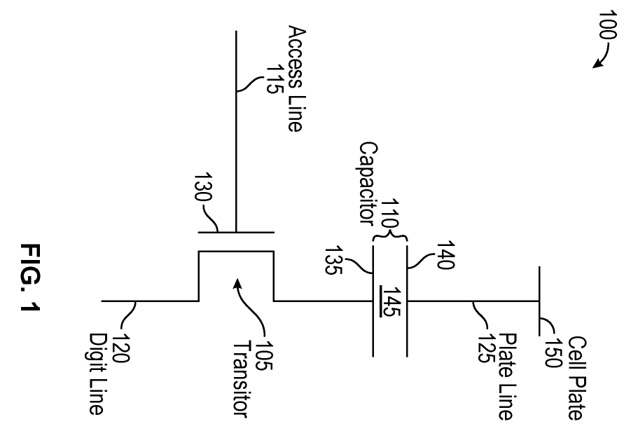

FIG. 1 is a circuit diagram of an example memory cell 100. In some implementations, the memory cell 100 is a ferroelectric memory cell. Alternatively, the memory cell 100 may be a linear dielectric memory cell or a paraelectric memory cell. As shown in FIG. 1, the memory cell 100 may include a transistor 105 (or another type of selection circuit) and a capacitor 110. The memory cell 100 may be accessed (e.g., written to, read from, and/or erased) using signals on a combination of lines that are coupled to the memory cell 100, shown as an access line 115 (sometimes called a “word line”), a digit line 120 (sometimes called a “bit line”), and a plate line 125.

The transistor 105 (sometimes called an access transistor) may include a gate 130. The capacitor 110 includes a bottom electrode 135 and a top electrode 140 separated by an insulator 145. In some implementations, the capacitor is a ferroelectric capacitor, and the insulator 145 is a ferroelectric insulator that comprises, consists of, or consists essentially of ferroelectric material. Alternatively, the capacitor may be a linear dielectric capacitor, and the insulator 145 may be a linear dielectric insulator that comprises, consists of, or consists essentially of linear dielectric material. Alternatively, the capacitor may be a paraelectric capacitor, and the insulator 145 may be a paraelectric insulator that comprises, consists of, or consists essentially of paraelectric material. When the access line 115 is activated (e.g., when a voltage is applied to the access line 115), the gate 130 coupled to the access line 115 may be activated. When the gate 130 is activated, the transistor 105 couples the digit line 120 to the bottom electrode 135 of the capacitor 110. A state of the memory cell 100 may then be written or read via the digit line 120.

The top electrode 140 of the capacitor 110 may be coupled to the plate line 125 and a cell plate 150. To write to (or program) the memory cell 100, the access line 115 may be activated, and a voltage may be applied across the capacitor 110 by controlling the voltage of the top electrode 140 (via the plate line 125 and/or the cell plate 150) and/or the bottom electrode 135 (via the digit line 120).

For a ferroelectric capacitor, the applied voltage creates an electric field, and the atoms in the ferroelectric material of the insulator 145 respond to the electric field to become arranged in a particular state (e.g., a particular orientation or polarization), which is representative of a data state (e.g., a logic “0” state or a logic “1” state). In some implementations, data may be stored using the capacitor 110 by controlling a voltage difference and/or a polarity difference of the capacitor 110 (e.g., of the insulator 145 between the bottom electrode 135 and the top electrode 140). For example, a voltage of the cell plate 150 and the digit line 120 may be controlled. In some implementations, a negative polarity of the insulator 145 as compared to the cell plate 150 results in a logic “0” state being stored in the capacitor 110, and a positive polarity of the insulator 145 as compared to the cell plate 150 results in a logic “1” state being stored in the capacitor 110. For a linear dielectric capacitor or a paraelectric capacitor, the cell plate 150 may grounded, and the capacitor 110 may be charged by applying a voltage to the bottom electrode 135 via the digit line 120.

To read the memory cell 100 (e.g., a state stored by the capacitor 110), the access line 115 may be activated, and a voltage may be applied to the plate line 125. Applying a voltage to the plate line 125 may cause a change in the stored charge on the capacitor 110. The stored charge on the capacitor 110 may increase or decrease the voltage on the digit line 120, which may be pre-charged to a reference value. A sense amplifier may amplify and/or sense this change in voltage on the digit line 120, and the sensed change in voltage may be used to determine the stored state of the capacitor 110. If the change in voltage satisfies a threshold, then the read operation indicates that a first state was stored in the capacitor 110 (e.g., a logic “1”), whereas if the change in voltage does not satisfy the threshold, then the read operation indicates that a second state was stored in the capacitor 110 (e.g., logic “0”). In some cases, multiple thresholds may be used, such as when the capacitor is capable of storing more than two data states (e.g., for a multi-level cell, a triple-level cell, and so on).

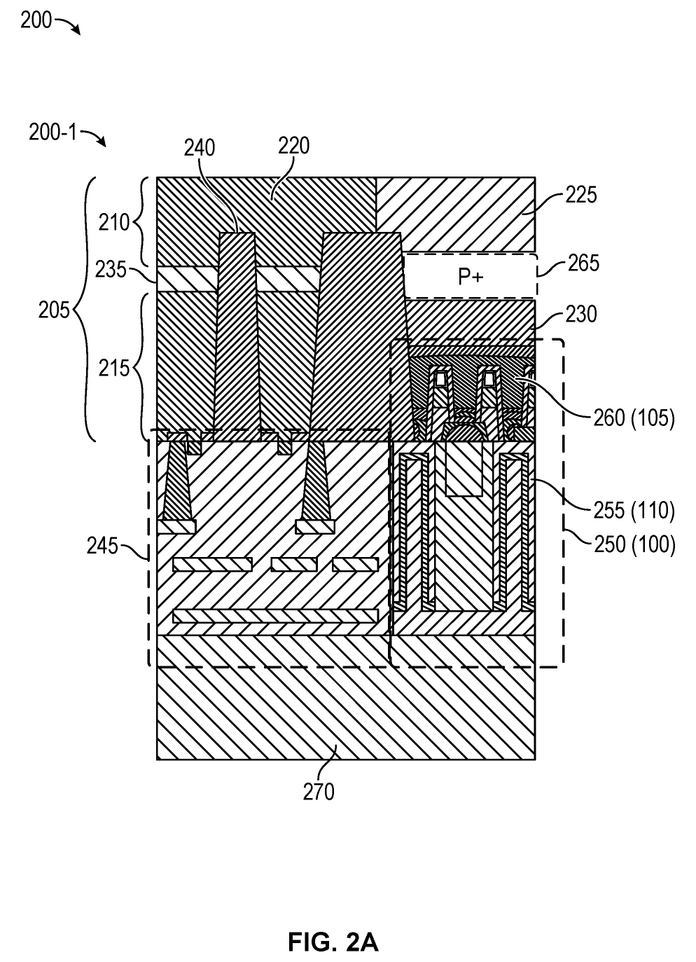

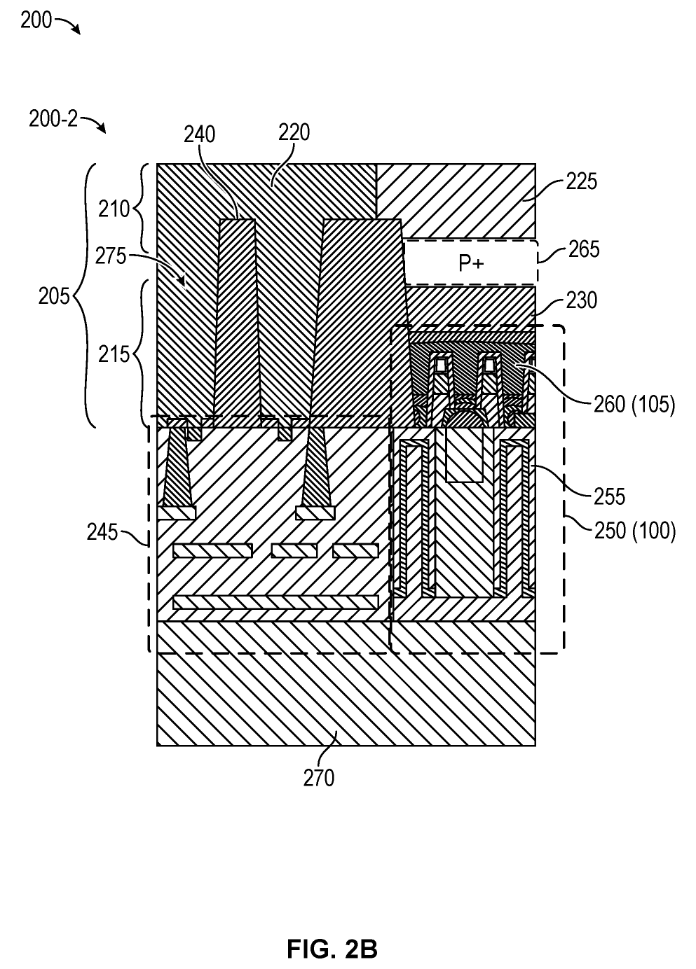

As described in greater detail in connection with FIGS. 2A-7 and elsewhere herein, the memory cell 100 may be included in a memory array region of a semiconductor device formed using a multi-layer stack. In addition to the memory array region, the semiconductor device may include a circuit region that is adjacent to the memory array region, and a doped semiconductive zone that is localized proximate to the memory array region (e.g., along bases of active areas of the memory array region and/or the memory cell 100). The doped semiconductive region may mitigate leakage from the memory array region, including the memory cell 100.

As indicated above, FIG. 1 is provided as an example. Other examples may differ from what is described with respect to FIG. 1.

FIGS. 2A and 2B are diagrammatic views of example implementations of a semiconductor device structure 200 described herein. The implementation of FIG. 2A includes semiconductor device structure 200-1 and the implementation of FIG. 2B includes semiconductor device structure 200-2.

As shown in the side view of FIG. 2A, the semiconductor device structure 200-1 includes a multi-layer stack 205 that includes a level 210 (e.g., a first level) and a level 215 (e.g., a second level) that span each other. The level 210 and/or the level 215 may each be a stratified level that contains multiple layers and/or features.

As an example, the level 210 may include a semiconductive layer 220 and an insulative layer 225. The semiconductive layer 220 may be a semiconductor and may comprise, consist of, or consist essentially of semiconductive material. The semiconductive material may comprise, consist of, or consist essentially of silicon (e.g., polycrystalline silicon). Alternatively, the semiconductive material may comprise, consist of, consist essentially of germanium, silicon germanium, silicon carbide, a type III-V compound (e.g., gallium arsenide, indium phosphide, gallium nitride, or aluminum gallium arsenide), and/or another suitable semiconductive material, among other examples. The insulative layer 225 may be an electrical insulator and may comprise, consist of, or consist essentially of insulative material. In some implementations, the insulative layer 225 comprises, consists of, or consists essentially of oxide. Alternatively, the insulative material may comprise, consist of, or consist essentially of silicon dioxide, silicon nitride, and/or another suitable insulative material, among other examples. Furthermore, the level 215 may include a semiconductive layer 230 that includes a same semiconductive material as the semiconductive layer 220.

In some implementations, a semiconductive layer 235 is between the level 210 and the level 215 (e.g., between the semiconductive layer 230 and the level 215). The semiconductive layer 235 may include a semiconductive material that is different than a semiconductive material included in the semiconductive layers 220 and 230. For example, and in a case in which the semiconductive layers 220 and 230 include silicon, the semiconductive layer 235 may include silicon germanium.

As further shown in FIG. 2A, the semiconductor structure 200-1 includes one or more isolation structures 240 that penetrate into and/or through portions of the multi-layer stack 205. The isolation structures 240 may be an electrical insulator and may comprise, consist of, or consist essentially of insulative material. The insulative material may comprise, consist of, or consist essentially of silicon dioxide and/or silicon nitride, among other examples. In some implementations, the isolation structures 240 provide electrical isolation within the semiconductor structure 200-1 to ensure electrical functionality of the semiconductor structure 200-1.

As further shown in FIG. 2A, the semiconductor structure 200-1 includes an integrated circuit region 245 and a memory array region 250. The integrated circuit region 245 may include a combination of conductive layers (e.g., titanium, tungsten, cobalt, nickel, platinum, and/or ruthenium), semiconductive layers, and/or insulative layers that form peripheral integrated circuitry adjacent to the memory array region 250. In some implementations, the integrated circuit region 245 includes complementary metal oxide semiconductor (CMOS) integrated circuitry. Alternatively, and in some implementations, the integrated circuit region includes n-channel metal oxide semiconductor (NMOS) integrated circuitry, p-channel metal oxide semiconductor (PMOS) integrated circuitry, gallium arsenide integrated circuitry, silicon on insulator (SOI) integrated circuitry, or other suitable integrated circuitry, among other examples.

The memory array region 250 may include a combination of semiconductive layers, conductive layers, and/or insulative layers that form one or more structures corresponding to the memory cell 100 of FIG. 1, including pillars 255 corresponding to the capacitor 110 of FIG. 1 and/or active areas 260 (e.g., channels) of the transistor 105 of FIG. 1. As further shown in FIG. 2A, the active areas 260 may extend into the level 215.

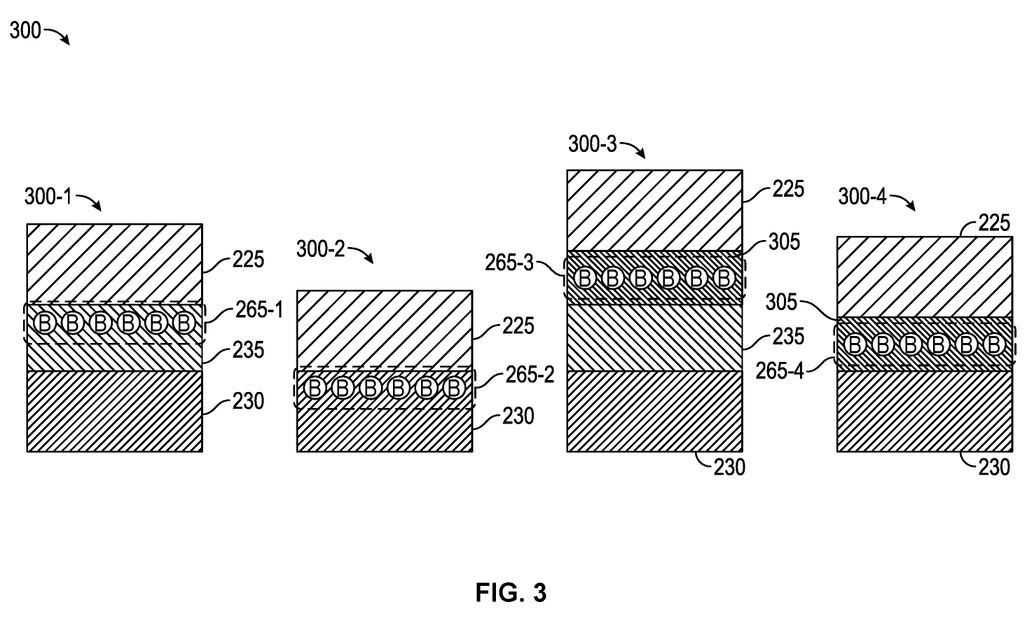

As further shown in FIG. 2A, a doped semiconductive region 265 may be between the semiconductive layer 230 and the insulative layer 225. As described in greater detail in connection with FIG. 3 and FIGS. 5A-6B, techniques to form the doped semiconductive region 265 may form the doped semiconductive region 265 proximate to the memory array region 250 to prevent leakage from the memory array region 250 (e.g., leakage from the active areas 260).

As further shown in FIG. 2A, the doped semiconductive region 265 may be a zone that is laterally-oriented (e.g., a lateral zone) and/or approximately rectangular. Additionally, or alternatively and as described in greater detail in connection with FIG. 3, the doped semiconductive region 265 may be localized (e.g., dopants included in the doped semiconductive region 265 may be confined and not diffuse into the memory array region 250 to inadvertently form leakage paths within the memory array region 250).

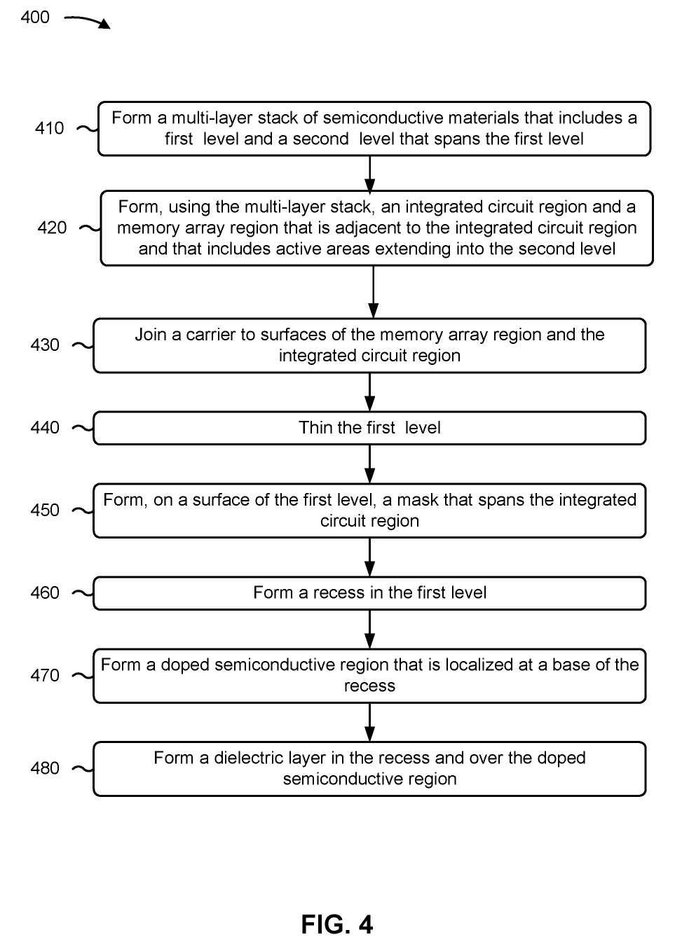

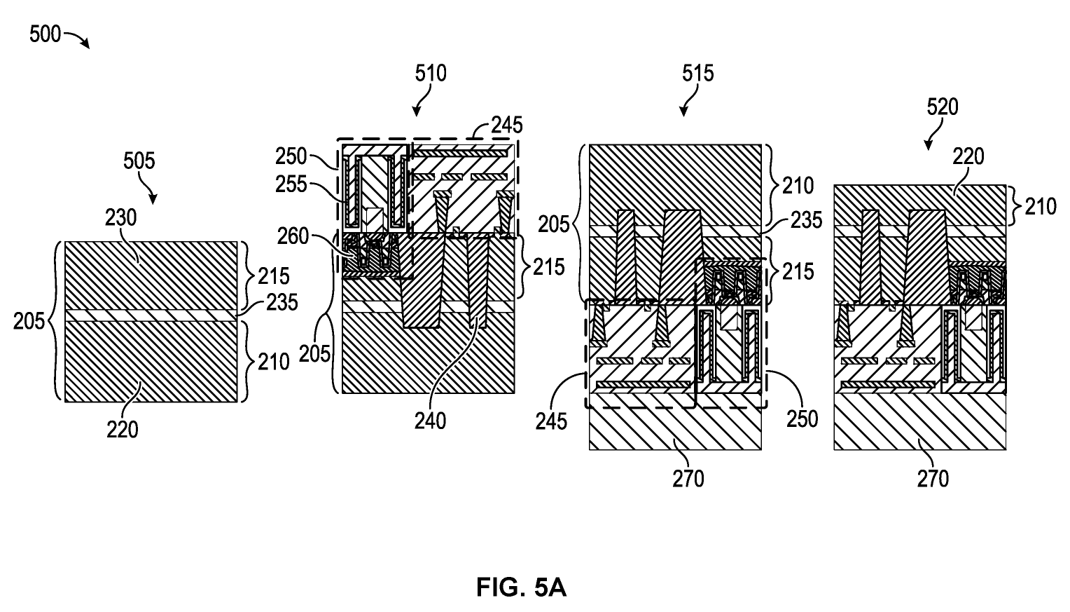

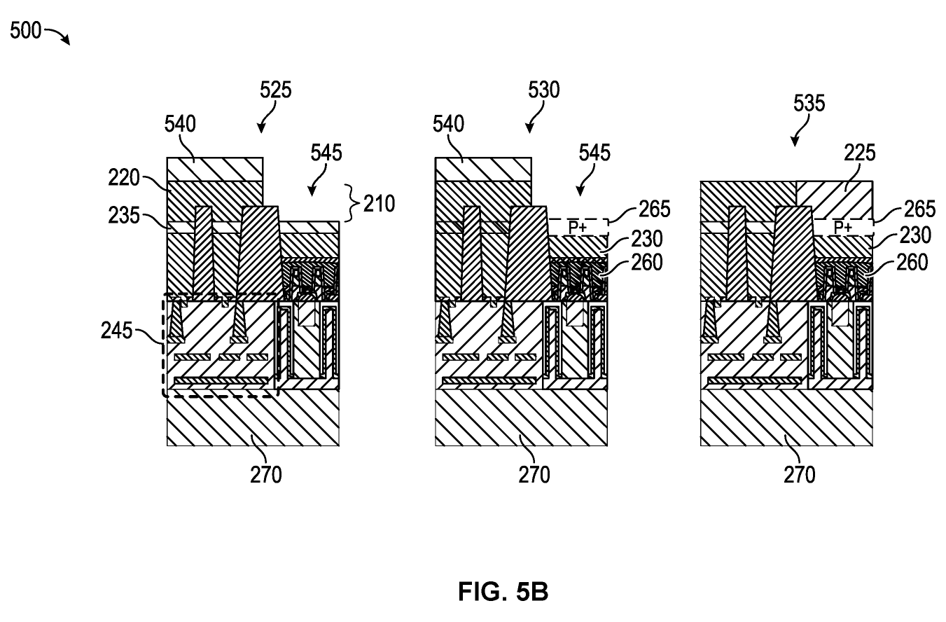

As further shown in FIG. 2A, the semiconductor structure 200-1 may include a carrier 270 (e.g., a silicon carrier, a glass carrier, or a ceramic carrier). As described in greater detail in connection with FIGS. 4, 5A, and 5B, techniques to form the semiconductor structure 200-1 may include forming the semiconductor structure 200-1 using the carrier 270, and the carrier 270 may be retained as part of the semiconductor structure 200-1 to provide mechanical rigidity and/or support.

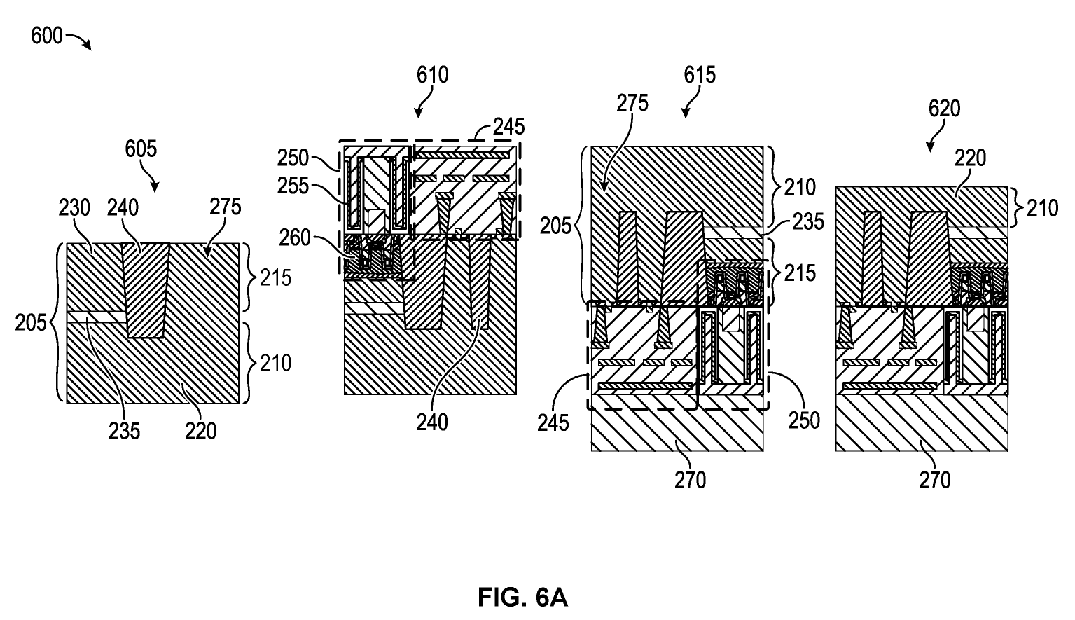

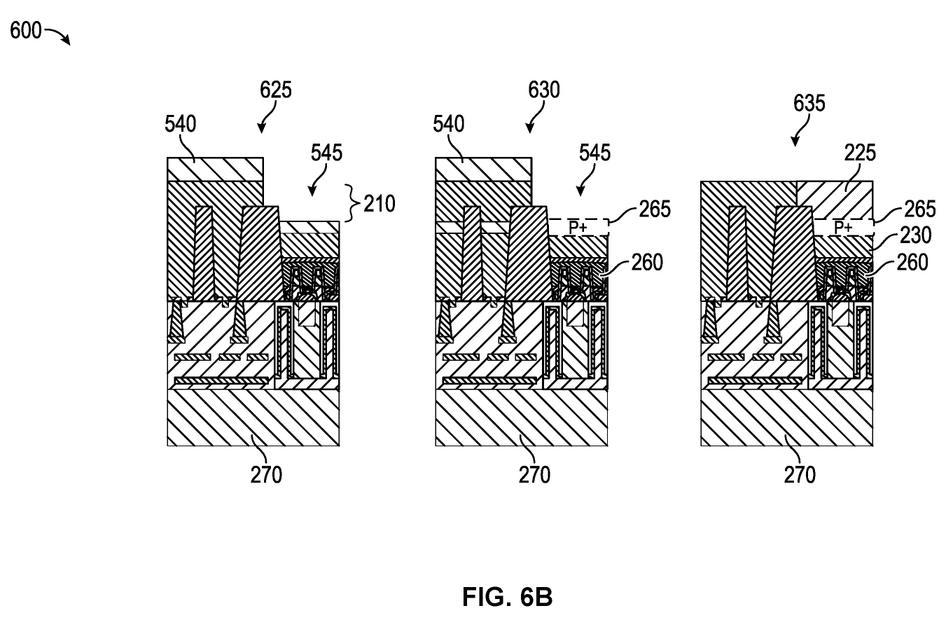

As shown in the side view of FIG. 2B, the semiconductor device structure 200-2 is similar to the semiconductor device structure 200-1. However, and in contrast to the semiconductor device structure 200-1, the semiconductor device structure 200-2 may not include a semiconductive layer (e.g., the semiconductive layer 235) between the semiconductive layer 230 and the level 215. Furthermore, and as described in greater detail in connection with FIGS. 4, 6A, and 6B, techniques to form the semiconductor structure 200-2 may include forming an epitaxial, semiconductive layer 275 as part of the level 215. The epitaxial, semiconductive layer 275 may directly conjoin with the semiconductive layer 220.

As indicated above, FIGS. 2A and 2B are provided as examples. Other examples may differ from what is described with regard to FIGS. 2A and 2B.

FIG. 3 includes diagrammatic views of example implementations 300 of a doped semiconductive region (e.g., the doped semiconductive region 265) described herein. In FIG. 3, the doped semiconductive region 265 includes boron as an example element that is used as a p-type dopant. However, other types of dopants (e.g., an n-type dopant), elements (e.g., gallium, indium, aluminum, phosphorous, or arsenic), and/or combinations of types of dopants and/or elements are within the scope of the present disclosure.

As shown in FIG. 3, and as part of implementation 300-1, the doped semiconductive region 265-1 is part of the semiconductive layer 235. In some implementations, and as an example, the doped semiconductive region 265-1 is formed using an implant operation to implant boron (or another suitable doping element) into the semiconductive layer 235. After the implant operation, the semiconductive layer 235 may include a doped portion (e.g., the doped semiconductive region 265-1) and an intrinsic (e.g., undoped) portion. In other words, the doped portion and the intrinsic portion are portions of a same layer of a semiconductive material. Furthermore, and as part of implementation 300-1, the semiconductive layer 230 is intrinsic (e.g., undoped).

As further shown in FIG. 3, and as part of implementation 300-2, the doped semiconductive region 265-2 is part of the semiconductive layer 230. The doped semiconductive region 265-2 may be formed using an implant operation to implant boron (or another suitable doping element) into the semiconductive layer 230. After implanting, the semiconductive layer 230 may include a doped portion (e.g., the doped semiconductive region 265-2) and an intrinsic (e.g., undoped) portion. In other words, the doped portion and the intrinsic portion are portions of a same layer of a semiconductive material.

As further shown in FIG. 3, and as part of implementation 300-3, the doped semiconductive region 265-3 is part of an in situ doped epitaxial, semiconductive layer 305 that is formed directly on the semiconductive layer 235 (e.g., the in situ doped epitaxial, semiconductive layer 305 is conjoined with the semiconductive layer 235). The in situ doped epitaxial, semiconductive layer 305 may be formed using an epitaxial growth operation that epitaxially grows a layer of silicon, silicon germanium, or another suitable semiconductive material and may directly incorporates boron (or another suitable doping element) into the layer during the operation. Furthermore, and as part of implementation 300-3, the semiconductive layer 230 and the semiconductive layer 235 are each intrinsic (e.g., undoped).

As further shown in FIG. 3, and as part of implementation 300-4, the doped semiconductive region 265-4 is part of an in situ doped epitaxial, semiconductive layer 305 that is formed directly on the semiconductive layer 230 (e.g., the in situ doped epitaxial, semiconductive layer 305 is conjoined with the semiconductive layer 230). The in situ doped epitaxial, semiconductive layer 305 may be formed using an epitaxial growth operation that epitaxially grows a layer of silicon, gallium arsenide, indium phosphide, gallium nitride, silicon carbide, or another suitable semiconductive material and directly incorporates boron (or another suitable doping element) into the layer during the operation. Furthermore, and as part of implementation 300-4, the semiconductive layer 230 is intrinsic (e.g., undoped).

As indicated above, FIG. 3 is provided as an example. Other examples may differ from what is described with regard to FIG. 3.

As described in connection with FIGS. 1-3, and in some implementations, a semiconductor device assembly (e.g., the semiconductor device structure 200-1 and/or the semiconductor device structure 200-2) includes a memory array region (e.g., the memory array region 250), an insulative layer (e.g., the insulative layer 225), an intrinsic semiconductive region (e.g., an undoped portion of the semiconductive layer 230 or an undoped portion of the semiconductive layer 235) between the memory array region and the insulative layer, and a doped semiconductive region (e.g., the doped semiconductive region 265-1, the doped semiconductive region 265-2, the doped semiconductive region 265-3, and/or the doped semiconductive region 265-4) that is contained within a lateral zone that is between the intrinsic semiconductive region and the insulative layer.

Additionally, or alternatively and in some implementations, an apparatus (e.g., the semiconductor device structure 200-1 and/or the semiconductor device structure 200-2) includes an integrated circuit region (e.g., the integrated circuit region 245), a memory array region (e.g., the memory array region 250) that is adjacent to the integrated circuit region, and a multi-layer semiconductor structure (e.g., the multi-layer stack 205). The multi-layer semiconductor structure includes a first level (e.g., the level 210) that spans the integrated circuit region and the memory array region. In some implementations, the first level includes a first semiconductive layer (e.g., the semiconductive layer 220) that spans at least a portion of the integrated circuit region and an insulative layer (e.g., the insulative layer 225) that spans at least a portion of the memory array region. The multi-layer semiconductor structure includes a second level (e.g., the level 215) that spans at least a portion of the integrated circuit region and at least a portion of the memory array region. In some implementations, the second level includes a second semiconductive layer (e.g., the semiconductor layer that 230) that spans at least a portion of the integrated circuit region. The apparatus further includes a doped semiconductive region (e.g., the doped semiconductive region 265) that is contained within an approximately rectangular zone between the insulative layer and the memory array region.

In these ways, the semiconductor device assembly and/or the apparatus may have a reduced thickness to accommodate scaling needs while satisfying one or more performance thresholds related to leakage, thereby promoting miniaturization and improving a quality and/or a reliability of the semiconductor device assembly and/or the apparatus. By promoting miniaturization and improving the quality and/or the reliability, an amount of resources used to support a market consuming the semiconductor device assembly and/or the apparatus (e.g., raw materials, semiconductor manufacturing tools, labor, and/or computing resources) is reduced.

FIG. 4 is a flowchart of an example method 400 of forming an integrated assembly or memory device (e.g., the semiconductor device structure 200-1 and/or the semiconductor device structure 200-2) that is thinned and that has a doped semiconductive region (e.g., the doped semiconductive region 265) that is localized proximate to a memory array region (e.g., the memory array region 250). In some implementations, one or more process blocks of FIG. 4 may be performed by various semiconductor manufacturing equipment.

As shown in FIG. 4, the method 400 may include forming a multi-layer stack (e.g., the multi-layer stack 205) of semiconductive materials that includes a first level (e.g., the level 210) and a second level (e.g., the level 215) that spans the first level (block 410). As further shown in FIG. 4, the method 400 may include forming, using the multi-layer stack, an integrated circuit region (e.g., the integrated circuit region 245) and a memory array region (e.g., the memory array region 250) that is adjacent to the integrated circuit region and that includes active areas (e.g., the active areas 260) extending into the second level (block 420). As further shown in FIG. 4, the method 400 may include joining a carrier (e.g., the carrier 270) to surfaces of the memory array region and the integrated circuit region (block 430). As further shown in FIG. 4, the method 400 may include thinning the first level (block 440). As further shown in FIG. 4, the method 400 may include forming, on a surface of the first level, a mask that spans the integrated circuit region (block 450). As further shown in FIG. 4, the method 400 may include forming a recess in the first level (block 460). As further shown in FIG. 4, the method 400 may include forming a doped semiconductive region (e.g., the doped semiconductive region 265) that is localized at a base of the recess (block 470). As further shown in FIG. 4, the method 400 may include forming a dielectric layer (e.g., the insulative layer 225) in the recess and over the doped semiconductive region (block 480).

The method 400 may include additional aspects, such as any single aspect or any combination of aspects described below and/or in connection with one or more other methods described elsewhere herein.

In a first aspect, forming the multi-layer stack includes forming a first silicon layer (e.g., the semiconductive layer 220) as part of the first level, forming a silicon germanium layer (e.g., the semiconductive layer 235) over the first silicon layer, and forming a second silicon layer (e.g., the semiconductive layer 230) on the silicon germanium layer as part of the second level.

In a second aspect, alone or in combination with the first aspect, forming the recess includes using an etching operation to remove a portion of the first silicon layer to expose a portion of the silicon germanium layer at the base of the recess.

In a third aspect, alone or in combination with one or more of the first and second aspects, forming the doped semiconductive region includes using an implant operation to dope the portion of the silicon germanium layer exposed at the base of the recess.

In a fourth aspect, alone or in combination with one or more of the first through third aspects, forming the doped semiconductive region includes forming an in situ doped epitaxial layer (e.g., the in situ doped epitaxial, semiconductive layer 305) on the portion of the silicon germanium layer exposed at the base of the recess.

In a fifth aspect, alone or in combination with one or more of the first through fourth aspects, forming the recess includes using a combination of one or more etching operations to remove a portion of the first silicon layer and a portion of the silicon germanium layer to expose a portion of the second silicon layer at the base of the recess.

In a sixth aspect, alone or in combination with one or more of the first through fifth aspects, forming the doped semiconductive region includes using an implant operation to dope the portion of the second silicon layer exposed at the base of the recess.

In a seventh aspect, alone or in combination with one or more of the first through sixth aspects, forming the doped semiconductive region includes forming an in situ doped epitaxial layer (e.g., the in situ doped epitaxial, semiconductive layer 305) on the portion of the second silicon layer exposed at the base of the recess.

In an eighth aspect, alone or in combination with one or more of the first through seventh aspects, the method 400 includes removing a portion of the second silicon layer to expose the silicon germanium layer, removing a portion of the silicon germanium layer to expose the first silicon layer, and forming a semiconductive layer (e.g., the epitaxial, semiconductive layer 275) that conjoins with the first silicon layer and backfills the removed portion of the second silicon layer and the removed portion of the silicon germanium layer.

In a ninth aspect, alone or in combination with one or more of the first through eighth aspects, forming the semiconductive layer includes using an epitaxial growth operation to form the semiconductive layer.

Although FIG. 4 shows example blocks of the method 400, in some implementations, the method 400 may include additional blocks, fewer blocks, different blocks, or differently arranged blocks than those depicted in FIG. 4. In some implementations, the method 400 may include forming the semiconductor device structure 200, an integrated assembly that includes semiconductor device structure 200, any part described herein of the semiconductor device structure 200, and/or any part described herein of an integrated assembly that includes the semiconductor device structure 200 For example, the method 400 may include forming one or more of the memory cell 100, the integrated circuit region 245, the memory array region 250, and/or the doped semiconductive region 265.

FIGS. 5A and 5B are diagrammatic views showing formation of a semiconductor device structure (e.g., the semiconductor device structure 200-1) at stages 505-535 of an example process 500 of forming the semiconductor device structure. In some implementations, the process 500 described below in connection with FIGS. 5A and 5B may correspond to the method 400 and/or one or more blocks of the method 400. However, the process described below is an example, and other example processes may be used to form the semiconductor device structure, an integrated assembly that includes the semiconductor device structure, and/or one or more parts of the semiconductor device structure and/or the integrated assembly.

As shown in FIG. 5A, and at stage 505, the process 500 may include forming the multi-layer stack 205, including the semiconductive layer 220 (e.g., the level 210) and the semiconductive layer 230 (e.g., the level 215) separated by the semiconductive layer 235. As an example, and in some implementations, a deposition tool may be used to deposit (e.g., grow) the semiconductive layer 235 over and/or on the semiconductive layer 220. Additionally, or alternatively, a deposition tool may be used to deposit (e.g., grow) the semiconductive layer 230 over and/or on the semiconductive layer 235.

As further shown in FIG. 5A, and at stage 510, the process 500 may include forming the integrated circuit region 245, the memory array region 250 (including the pillars 255 and/or the active areas 260), and/or the isolation structure 240 using the multi-layer stack 205. As an example, and in some implementations, a deposition tool, a lithography tool, and an etch tool may be used to deposit (e.g., grow), pattern, and etch one or more semiconductive layers, one or more conductive layers, and one or more insulative layers as part of forming the integrated circuit region 245, the memory array region 250, and/or the isolation structures 240.

As further shown in FIG. 5A, and at stage 515, the process 500 may include inverting the multi-layer stack 205 and joining surfaces of the memory array region 250 and the integrated circuit region 245 with the carrier 270. As an example, a bonding tool may be used to join surfaces of the memory array region 250 and the integrated circuit region 245 with the carrier 270.

As further shown in FIG. 5A, and at stage 520, the process 500 may include thinning the level 210 (e.g., thinning the semiconductive layer 220). As an example, a planarization tool may be used to perform a chemical-mechanical planarization operation that thins the level 210.

As shown in FIG. 5B, and at stage 525, the process 500 may include forming, on a surface of the level 210, a mask 540 that spans the integrated circuit region 245. As an example, a deposition tool, a lithography tool, and/or an etch tool may perform a series of operations that form the mask 540 (e.g., a hard mask formed from an insulative material such as silicon nitride) on the surface of the level 210. Furthermore, at stage 525 and after formation of the mask 540, the process 500 may include forming a recess 545 in the level 210 by removing an unmasked portion of the level 210. As an example, an etch tool may be used to perform a selective etch operation that removes a portion of the semiconductive layer 220 to form the recess 545 and expose a portion of the semiconductive layer 235.

As further shown in FIG. 5B, and at stage 530, the process 500 may include forming the doped semiconductive region 265 at a base of the recess 545. As an example, and as described in connection with implementation 300-1 of FIG. 3, an implant tool may be used to implant a dopant into the semiconductive layer 235. As another example, and as described in connection with implementation 300-2 of FIG. 3, an etch tool may be used to remove a portion of the semiconductive layer 235 to expose the semiconductive layer 230, and an implant tool may be used to implant a dopant in the semiconductive layer 230. As another example, and as described in connection with implementation 300-3 of FIG. 3, a deposition tool may be used to form an in situ doped semiconductive layer (e.g., the in situ doped epitaxial, semiconductive layer 305) over and/or on the semiconductive layer 235. As another example, and as described in connection with implementation 300-4 of FIG. 3, an etch tool may be used to remove a portion of the semiconductive layer 235 to expose the semiconductive layer 230, and a deposition tool may be used to form an in situ doped semiconductive layer (e.g., the in situ doped epitaxial, semiconductive layer 305) over and/or on the semiconductive layer 230.

As further shown in FIG. 5B, and at stage 535, the process 500 may include forming the insulative layer 225 over the doped semiconductive region 265. As an example, a deposition tool may be used to form (e.g., grow) the insulative layer 225 over and/or on the doped semiconductive region 265 to fill the recess 545. Additionally, or alternatively and as part of stage 535, a planarization tool may be used to perform a chemical-mechanical planarization operation that planarizes the insulative layer 225.

As indicated above, the process steps described in connection with FIGS. 5A and 5B are provided as examples. Other examples may differ from what is described with respect to FIGS. 5A and 5B. The structure shown in FIG. 5B may be equivalent to the semiconductor device structure 200-1 described elsewhere herein. In process steps above that describe depositing and/or forming material, such material may be formed, for example, using chemical vapor deposition, atomic layer deposition, physical vapor deposition, or another deposition technique. In process steps above that describe etching and/or removing material, such material may be etched and/or removed, for example, using a wet etching technique (e.g., wet chemical etching), a dry etching technique (e.g., plasma etching), an ion etching technique (e.g., sputtering or reactive ion etching), atomic layer etching, or another etching technique.

FIGS. 6A and 6B are diagrammatic views showing formation of a semiconductor device structure (e.g., the semiconductor device structure 200-2) at stages 605-635 of an example process 600 of forming the semiconductor device structure. In some implementations, the process 600 described below in connection with FIGS. 6A and 6B may correspond to the method 400 and/or one or more blocks of the method 400. However, the process described below is an example, and other example processes may be used to form the semiconductor device structure, an integrated assembly that includes the semiconductor device structure, and/or one or more parts of the semiconductor device structure and/or the integrated assembly.

As shown in FIG. 6A, and at stage 605, the process 600 may include forming the multi-layer stack 205. Forming the multi-layer stack 205 may include forming the semiconductive layer 220 as part of the level 210, the semiconductive layer 235, and the semiconductive layer 230 as part of the level 215. As an example, and in some implementations, a deposition tool may be used to deposit (e.g., grow) the semiconductive layer 235 over and/or on the semiconductive layer 220. Additionally, or alternatively, a deposition tool may be used to deposit (e.g., grow) the semiconductive layer 230 over and/or on the semiconductive layer 235.

Furthermore, and as part of stage 605, the process 600 may include forming one or more of the isolation structures 240. As an example, and in some implementations, a lithography tool and an etch tool may be used to deposit (e.g., grow), pattern and etch the semiconductive layer 230, and a deposition tool may be used to deposit (e.g., grow) the isolation structures 240.

Furthermore, and as part of stage 605, the process 600 may include forming the epitaxial, semiconductive layer 275 over and/or on the semiconductive layer 220. As an example, and in some implementations, a lithography tool and an etch tool may be used to remove portions of the semiconductive layer 230 and the semiconductive layer 235 to expose the semiconductive layer 220, and a deposition tool may be used to deposit (e.g., grow) the epitaxial, semiconductive layer 275 over and/or on the semiconductive layer 220.

As further shown in FIG. 6A, and at stage 610, the process 600 may include forming the integrated circuit region 245 and the memory array region 250 (including the pillars 255 and/or the active areas 260), and/or additional isolation structures 240 using the multi-layer stack 205. As an example, and in some implementations, a deposition tool, a lithography tool, and an etch tool may be used to deposit (e.g., grow), pattern, and etch one or more semiconductive layers, one or more conductive layers, and one or more insulative layers as part of forming the integrated circuit region 245, the memory array region 250, and/or the additional isolation structures 240.

As further shown in FIG. 6A, and at stage 615, the process 600 may include inverting the multi-layer stack 205 and joining surfaces of the memory array region 250 and the integrated circuit region 245 with the carrier 270. As an example, a bonding tool may be used to join surfaces of the memory array region 250 and the integrated circuit region 245 with the carrier 270.

As further shown in FIG. 6A, and at stage 620, the process 600 may include thinning the level 210 (e.g., thinning the semiconductive layer 220). As an example, a planarization tool may be used to perform a chemical-mechanical planarization operation that thins the level 210.

As shown in FIG. 6B, and at stage 625, the process 600 may include forming, on a surface of the level 210, the mask 540 that spans the integrated circuit region 245. As an example, a deposition tool, a lithography tool, and/or an etch tool may perform a series of operations that form the mask 540 (e.g., a hard mask formed from an insulative material such as silicon nitride) on the surface of the level 210. Furthermore, and at stage 625 and after formation of the mask 540, the process 500 may include forming the recess 545 in the level 210 by removing an unmasked portion of the level 210. As an example, an etch tool may be used to perform a selective etch operation that removes a portion of the semiconductive layer 220 to form the recess 545 and expose a portion of the semiconductive layer 235.

As further shown in FIG. 6B, and at stage 630, the process 600 may include forming the doped semiconductive region 265 at a base of the recess 545. As an example, and as described in connection with implementation 300-1 of FIG. 3, an implant tool may be used to implant a dopant into the semiconductive layer 235. As another example, and as described in connection with implementation 300-2 of FIG. 3, an etch tool may be used to remove a portion of the semiconductive layer 235 to expose the semiconductive layer 230, and an implant tool may be used to implant a dopant in the semiconductive layer 230. As another example, and as described in connection with implementation 300-3 of FIG. 3, a deposition tool may be used to form an in situ doped semiconductive layer (e.g., the in situ doped epitaxial, semiconductive layer 305) over and/or on the semiconductive layer 235. As another example, and as described in connection with implementation 300-4 of FIG. 3, an etch tool may be used to remove a portion of the semiconductive layer 235 to expose the semiconductive layer 230, and a deposition tool may be used to form an in situ doped semiconductive layer (e.g., the in situ doped epitaxial, semiconductive layer 305) over and/or on the semiconductive layer 230.

As further shown in FIG. 6B, and at stage 635, the process 600 may include forming the insulative layer 225 over the doped semiconductive region 265. As an example, a deposition tool may be used to form (e.g., grow) the insulative layer 225 over and/or on the doped semiconductive region 265 to fill the recess 545. Additionally, or alternatively and as part of stage 535, a planarization tool may be used to perform a chemical-mechanical planarization operation that planarizes the insulative layer 225.

As indicated above, the process steps described in connection with FIGS. 6A and 6B are provided as examples. Other examples may differ from what is described with respect to FIGS. 6A and 6B. The structure shown in FIG. 6B may be equivalent to the semiconductor device structure 200-2 described elsewhere herein. In process steps above that describe forming material, such material may be formed, for example, using chemical vapor deposition, atomic layer deposition, physical vapor deposition, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, or another etching technique.

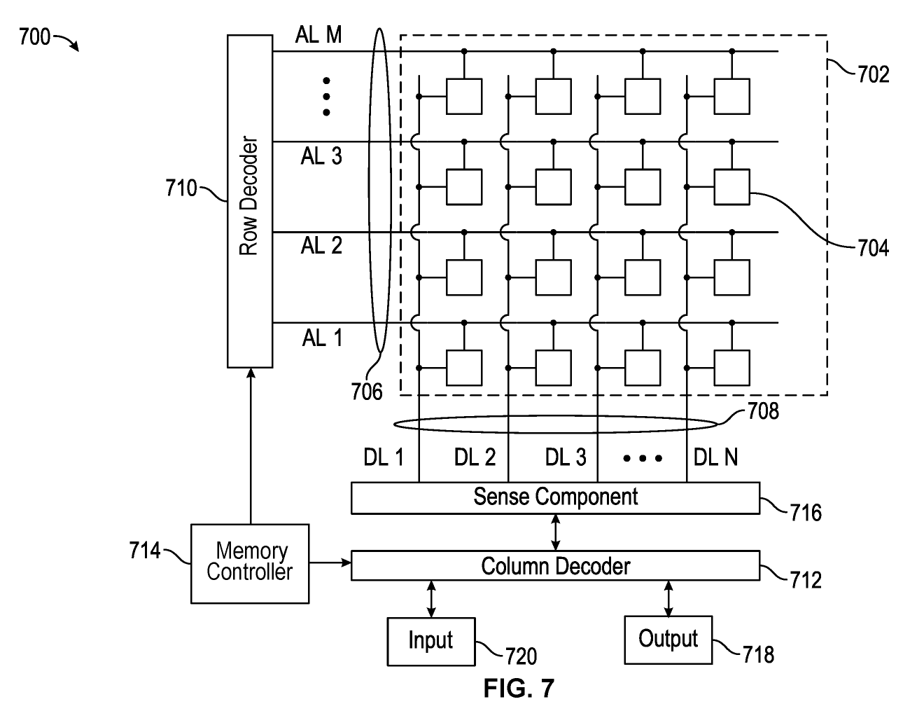

FIG. 7 is a diagrammatic view of an example memory device 700. The memory device 700 may include a memory array 702 that includes multiple memory cells 704. A memory cell 704 is programmable or configurable into a data state of multiple data states (e.g., two or more data states). For example, a memory cell 704 may be set to a particular data state at a particular time, and the memory cell 704 may be set to another data state at another time. A data state may correspond to a value stored by the memory cell 704. The value may be a binary value, such as a binary 0 or a binary 1, or may be a fractional value, such as 0.5, 1.5, or the like. A memory cell 704 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (i.e., cycling) may be performed on memory cells 704 by activating or selecting the appropriate access line 706 (shown as access lines AL 1 through AL M) and digit line 708 (shown as digit lines DL 1 through DL N). An access line 706 may also be referred to as a “row line” or a “word line,” and a digit line 708 may also be referred to a “column line” or a “bit line.” Activating or selecting an access line 706 or a digit line 708 may include applying a voltage to the respective line. An access line 706 and/or a digit line 708 may comprise, consist of, or consist essentially of a conductive material, such as a metal (e.g., copper, aluminum, gold, titanium, or tungsten) and/or a metal alloy, among other examples. In FIG. 7, each row of memory cells 704 is connected to a single access line 706, and each column of memory cells 704 is connected to a single digit line 708. By activating one access line 706 and one digit line 708 (e.g., applying a voltage to the access line 706 and digit line 708), a single memory cell 704 may be accessed at (e.g., is accessible via) the intersection of the access line 706 and the digit line 708. The intersection of the access line 706 and the digit line 708 may be called an “address” of a memory cell 704.

In some implementations, the logic storing device of a memory cell 704, such as a capacitor, may be electrically isolated from a corresponding digit line 708 by a selection component, such as a transistor. The access line 706 may be connected to and may control the selection component. For example, the selection component may be a transistor, and the access line 706 may be connected to the gate of the transistor. Activating the access line 706 results in an electrical connection or closed circuit between the capacitor of a memory cell 704 and a corresponding digit line 708. The digit line 708 may then be accessed (e.g., is accessible) to either read from or write to the memory cell 704.

A row decoder 710 and a column decoder 712 may control access to memory cells 704. For example, the row decoder 710 may receive a row address from a memory controller 714 and may activate the appropriate access line 706 based on the received row address. Similarly, the column decoder 712 may receive a column address from the memory controller 714 and may activate the appropriate digit line 708 based on the column address.

Upon accessing a memory cell 704, the memory cell 704 may be read (e.g., sensed) by a sense component 716 to determine the stored data state of the memory cell 704. For example, after accessing the memory cell 704, the capacitor of the memory cell 704 may discharge onto its corresponding digit line 708. Discharging the capacitor may be based on biasing, or applying a voltage, to the capacitor. The discharging may induce a change in the voltage of the digit line 708, which the sense component 716 may compare to a reference voltage (not shown) to determine the stored data state of the memory cell 704. For example, if the digit line 708 has a higher voltage than the reference voltage, then the sense component 716 may determine that the stored data state of the memory cell 704 corresponds to a first value, such as a binary 1. Conversely, if the digit line 708 has a lower voltage than the reference voltage, then the sense component 716 may determine that the stored data state of the memory cell 704 corresponds to a second value, such as a binary 0. The detected data state of the memory cell 704 may then be output (e.g., via the column decoder 712) to an output component 718 (e.g., a data buffer). A memory cell 704 may be written (e.g., set) by activating the appropriate access line 706 and digit line 708. The column decoder 712 may receive data, such as input from input component 720, to be written to one or more memory cells 704. A memory cell 704 may be written by applying a voltage across the capacitor of the memory cell 704.

The memory controller 714 may control the operation (e.g., read, write, re-write, refresh, and/or recovery) of the memory cells 704 via the row decoder 710, the column decoder 712, and/or the sense component 716. The memory controller 714 may generate row address signals and column address signals to activate the desired access line 706 and digit line 708. The memory controller 714 may also generate and control various voltages used during the operation of the memory array 702.

In some implementations, the memory device 700 includes the semiconductor device structure 200 and/or an integrated assembly that includes the semiconductor device structure 200. For example, the memory array 702 may include the semiconductor device structure 200 and/or an integrated assembly that includes the semiconductor device structure 200. Additionally, or alternatively, the memory cell 704 may include a memory cell described elsewhere herein.

As indicated above, FIG. 7 is provided as an example. Other examples may differ from what is described with respect to FIG. 7.

In some implementations, a semiconductor device assembly includes a memory array region; an insulative layer; an intrinsic semiconductive region between the memory array region and the insulative layer; and a doped semiconductive region that is contained within a lateral zone that is between the intrinsic semiconductive region and the insulative layer.

In some implementations, an apparatus includes an integrated circuit region; a memory array region that is adjacent to the integrated circuit region; and a multi-layer semiconductor structure, comprising: a first level that spans the integrated circuit region and the memory array region, comprising: a first semiconductive layer that spans at least a portion of the integrated circuit region, and an insulative layer that spans at least a portion of the memory array region; a second level that spans the integrated circuit region and the memory array region, comprising: a second semiconductive layer that spans at least a portion of the integrated circuit region; and a doped semiconductive region that is contained within an approximately rectangular zone between the insulative layer and the memory array region.

In some implementations, a method includes forming a multi-layer stack of semiconductive materials that includes a first level and a second level that spans the first level; forming, using the multi-layer stack, an integrated circuit region and a memory array region that is adjacent to the integrated circuit region and that includes active areas extending into the second level; joining a carrier to surfaces of the memory array region and the integrated circuit region; thinning the first level; forming, on a surface of the first level, a mask that spans the integrated circuit region; forming a recess in the first level; forming a doped semiconductive region that is localized at a base of the recess; and forming a dielectric layer in the recess and over the doped semiconductive region.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element’s relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

In some cases, a single reference number is shown to refer to a surface, or fewer than all instances of a part may be labeled with all surfaces of that part. All instances of the part may include associated surfaces of that part despite not every surface being labeled.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a + b, a + c, b + c, and a + b + c, as well as any combination with multiples of the same element (e.g., a + a, a + a + a, a + a + b, a + a + c, a + b + b, a + c + c, b + b, b + b + b, b + b + c, c + c, and c + c + c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a memory array region;
an insulative layer;
an intrinsic semiconductive region between the memory array region and the insulative layer; and
a doped semiconductive region that is contained within a lateral zone that is between the intrinsic semiconductive region and the insulative layer.

2. The semiconductor device assembly of claim 1, wherein the intrinsic semiconductive region and the doped semiconductive region are portions of a same layer of a semiconductive material.

3. The semiconductor device assembly of claim 1, wherein the intrinsic semiconductive region comprises:
a first semiconductive material, and
wherein the doped semiconductive region comprises:
a second semiconductive material that is different than the first semiconductive material.

4. The semiconductor device assembly of claim 3, wherein the first semiconductive material comprises silicon.

5. The semiconductor device assembly of claim 3, wherein the second semiconductive material comprises silicon germanium.

6. The semiconductor device assembly of claim 3, wherein the doped semiconductive region includes a p-type dopant.

7. An apparatus, comprising:
an integrated circuit region;
a memory array region that is adjacent to the integrated circuit region; and
a multi-layer semiconductor structure, comprising:
a first level that spans the integrated circuit region and the memory array region, comprising:
a first semiconductive layer that spans at least a portion of the integrated circuit region, and
an insulative layer that spans at least a portion of the memory array region;
a second level that spans the integrated circuit region and the memory array region, comprising:
a second semiconductive layer that spans at least a portion of the integrated circuit region; and
a doped semiconductive region that is contained within an approximately rectangular zone between the insulative layer and the memory array region.

8. The apparatus of claim 7, wherein the doped semiconductive region comprises an in situ doped semiconductive layer that is conjoined with the second semiconductive layer.

9. The apparatus of claim 7, further comprising a third semiconductive layer between the first level and the second level.

10. The apparatus of claim 9, wherein the doped semiconductive region comprises an in situ doped semiconductive layer that is conjoined with the third semiconductive layer and that is between the third semiconductive layer and the insulative layer.

11. A method, comprising:
forming a multi-layer stack of semiconductive materials that includes a first level and a second level that spans the first level;
forming, using the multi-layer stack, an integrated circuit region and a memory array region that is adjacent to the integrated circuit region and that includes active areas extending into the second level;
joining a carrier to surfaces of the memory array region and the integrated circuit region;
thinning the first level;
forming, on a surface of the first level, a mask that spans the integrated circuit region;
forming a recess in the first level;
forming a doped semiconductive region that is localized at a base of the recess; and
forming a dielectric layer in the recess and over the doped semiconductive region.

12. The method of claim 11, wherein forming the multi-layer stack includes:
forming a first silicon layer as part of the first level,
forming a silicon germanium layer over the first silicon layer, and
forming a second silicon layer on the silicon germanium layer as part of the second level.

13. The method of claim 12, wherein forming the recess includes:
using an etching operation to remove a portion of the first silicon layer to expose a portion of the silicon germanium layer at the base of the recess.

14. The method of claim 13, wherein forming the doped semiconductive region includes:
using an implant operation to dope the portion of the silicon germanium layer exposed at the base of the recess.

15. The method of claim 13, wherein forming the doped semiconductive region includes:
forming an in situ doped epitaxial layer on the portion of the silicon germanium layer exposed at the base of the recess.

16. The method of claim 12, wherein forming the recess includes:
using a combination of one or more etching operations to remove a portion of the first silicon layer and a portion of the silicon germanium layer to expose a portion of the second silicon layer at the base of the recess.

17. The method of claim 16, wherein forming the doped semiconductive region includes:
using an implant operation to dope the portion of the second silicon layer exposed at the base of the recess.

18. The method of claim 16, wherein forming the doped semiconductive region includes:
forming an in situ doped epitaxial layer on the portion of the second silicon layer exposed at the base of the recess.

19. The method of claim 12, further comprising:
removing a portion of the second silicon layer to expose the silicon germanium layer;
removing a portion of the silicon germanium layer to expose the first silicon layer; and
forming a semiconductive layer that conjoins with the first silicon layer and backfills the removed portion of the second silicon layer and the removed portion of the silicon germanium layer.

20. The method of claim 19, wherein forming the semiconductive layer includes:
using an epitaxial growth operation to form the semiconductive layer.
